(19) United States
(12) Patent Application Publication
(10) Pub. No.: US 2026/0068410 A1
(43) Pub. Date: Mar. 5, 2026

(54) LIGHT EMITTING DEVICE AND ELECTRONIC EQUIPMENT

(71) Applicant: SEIKO EPSON CORPORATION, Tokyo (JP)

(72) Inventor: Shinji TERAO, FUJIMI-MACHI (JP)

(73) Assignee: SEIKO EPSON CORPORATION, Tokyo (JP)

(21) Appl. No.: 19/309,627

(22) Filed: Aug. 26, 2025

(30) Foreign Application Priority Data
Aug. 27, 2024 (JP) 2024-145263

(51) Int. Cl. H10H 29/856; H10H 20/819; H10H 29/01; H10H 29/80

(52) U.S. Cl. CPC H10H 29/856; H10H 20/819; H10H 29/842; H10H 29/011; H10H 29/0363

(57) ABSTRACT

A light emitting device according to an aspect includes a first stacked body including a first semiconductor layer of a first conductivity type, a second semiconductor layer of a second conductivity type, and a first light emitting layer, a first insulating layer provided on a side surface of the first stacked body, a first metal layer provided on the first insulating layer and located on a side of the first stacked body, a first electrode provided between the substrate and the first stacked body and electrically coupled to the first semiconductor layer, a second electrode provided on a side of the first stacked body opposite to the first electrode and electrically coupled to the second semiconductor layer, a first transparent layer provided on a side of the second electrode opposite to the first stacked body, a first lens provided on a side of the first transparent layer opposite to the second electrode and overlapping the first light emitting layer in a plan view, and a reflective member made of metal provided on sides of the first lens and the first transparent layer. The reflective member is electrically coupled to the second electrode.

The present application is based on, and claims priority from JP Application Serial Number 2024-145263, filed Aug. 27, 2024, the disclosure of which is hereby incorporated by reference herein in its entirety.

### BACKGROUND

### Technical Field

The present disclosure relates to a light emitting device and electronic equipment.

### Description of Related Art

A light emitting element such as a light emitting diode (LED) is applied to a light source of a display device or the like.

For example, JP-A-2021-82687 describes an image display element in which micro light emitting elements are arranged in an array. The micro light emitting element includes an excitation light emitting element that generates excitation light, a reflective wall surrounding the excitation light emitting element, and a wavelength conversion material disposed inside the reflective wall.

The excitation light emitting element is formed by forming a main body obtained by dividing a nitride semiconductor layer, depositing a transparent insulating film covering all surfaces excluding a bottom part of the main body, opening a contact hole in an upper part of the main body, and depositing a transparent electrode on all the surfaces.

The reflective wall is formed by forming a base material serving as a wall to surround the main body, depositing a reflective material film on all the surfaces, and removing the reflective material film covering the upper surface and the side surfaces of the main body using a photolithography technique and an etching technique.

JP-A-2021-82687 is an example of the related art.

However, in the image display element described in JP-A-2021-82687, when the reflective material film covering the upper surface and the side surfaces of the main body is removed by etching, the transparent electrode is etched and disconnection or an increase in resistance is likely to occur.

### SUMMARY

According to an aspect of the present disclosure, there is provided a light emitting device including:
a substrate;
a first stacked body including a first semiconductor layer of a first conductivity type, a second semiconductor layer of a second conductivity type different from the first conductivity type, and a first light emitting layer provided between the first semiconductor layer and the second semiconductor layer;
a first insulating layer provided on a side surface of the first stacked body;
a first metal layer provided on the first insulating layer and located on a side of the first stacked body;
a first electrode provided between the substrate and the first stacked body and electrically coupled to the first semiconductor layer;
a second electrode provided on a side of the first stacked body opposite to the first electrode and electrically coupled to the second semiconductor layer;
a first transparent layer provided on a side of the second electrode opposite to the first stacked body;
a first lens provided on a side of the first transparent layer opposite to the second electrode and overlapping the first light emitting layer in a plan view; and
a reflective member made of metal provided on sides of the first lens and the first transparent layer, wherein
the reflective member is electrically coupled to the second electrode.

According to an aspect of the present disclosure, there is provided electronic equipment including the light emitting device according to the aspect explained above.

### BRIEF DESCRIPTION OF THE DRAWINGS

FIG. 1 is a cross-sectional view schematically illustrating a light emitting device according to a first embodiment.

FIG. 2 is a plan view schematically illustrating the light emitting device according to the first embodiment.

FIG. 3 is a plan view schematically illustrating the light emitting device according to the first embodiment.

FIG. 4 is a plan view schematically illustrating the light emitting device according to the first embodiment.

FIG. 5 is a cross-sectional view schematically illustrating the light emitting device according to the first embodiment.

FIG. 6 is a cross-sectional view schematically illustrating a manufacturing process for the light emitting device according to the first embodiment.

FIG. 7 is a cross-sectional view schematically illustrating the manufacturing process for the light emitting device according to the first embodiment.

FIG. 8 is a cross-sectional view schematically illustrating the manufacturing process for the light emitting device according to the first embodiment.

FIG. 9 is a cross-sectional view schematically illustrating the manufacturing process for the light emitting device according to the first embodiment.

FIG. 10 is a cross-sectional view schematically illustrating the manufacturing process for the light emitting device according to the first embodiment.

FIG. 11 is a cross-sectional view schematically illustrating the manufacturing process for the light emitting device according to the first embodiment.

FIG. 12 is a cross-sectional view schematically illustrating the manufacturing process for the light emitting device according to the first embodiment.

FIG. 13 is a cross-sectional view schematically illustrating the manufacturing process for the light emitting device according to the first embodiment.

FIG. 14 is a cross-sectional view schematically illustrating the manufacturing process for the light emitting device according to the first embodiment.

FIG. 15 is a cross-sectional view schematically illustrating a light emitting device according to a second embodiment.

FIG. 16 is a diagram schematically illustrating a projector according to a third embodiment.

FIG. 17 is a plan view schematically illustrating a display according to a fourth embodiment.

FIG. 18 is a cross-sectional view schematically illustrating a display according to a fourth embodiment.

FIG. 19 is a perspective view schematically illustrating a head-mounted display according to a fifth embodiment.

FIG. 20 is a diagram schematically illustrating an image forming device and a light guide device of the head-mounted display according to the fifth embodiment.

### DESCRIPTION OF THE EMBODIMENTS

Preferred embodiments of the present disclosure are explained in detail below with reference to the drawings. Note that the embodiments explained below do not unreasonably limit the content of the present disclosure set forth in the appended claims. Not all of components explained below are always essential elements of the present disclosure.

### 1. First Embodiment

### 1.1. Light Emitting Device

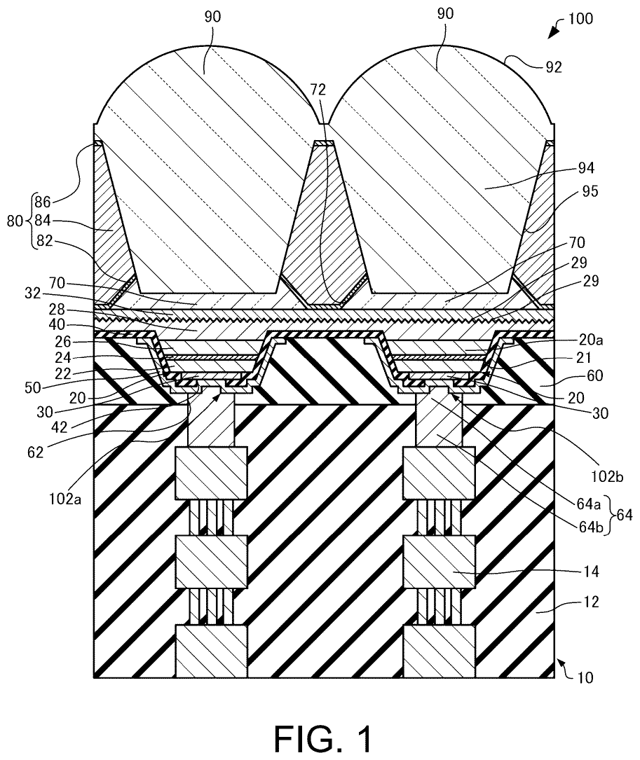

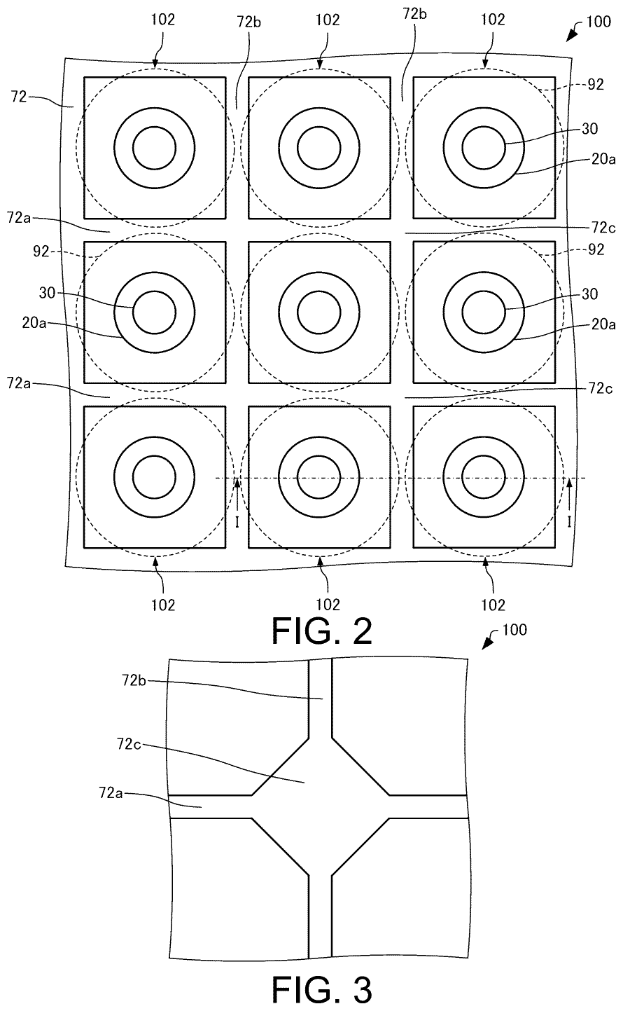

First, a light emitting device according to a first embodiment is explained with reference to the drawings. FIG. 1 is a cross-sectional view schematically illustrating a light emitting device 100 according to the first embodiment. FIG. 2 is a plan view schematically illustrating the light emitting device 100 according to the first embodiment. FIG. 1 is an I-I line cross-sectional view of FIG. 2.

As illustrated in FIGS. 1 and 2, the light emitting device 100 includes, for example, a substrate 10, a stacked body 20, a p-electrode 30, an n-electrode 32, an insulating layer 40, a metal layer 50, an interlayer insulating layer 60, a transparent layer 70, a reflective member 80, and a lens 90. The stacked body 20, the p-electrode 30, the n-electrode 32, the insulating layer 40, and the metal layer 50 configure a light emitting element 102. The light emitting element 102 is an LED. For convenience, in FIG. 1, members other than a first taper section 20a of the stacked body 20 and the p-electrode 30 are not illustrated and an emission surface 92 of the lens 90 is illustrated to be transparent.

As illustrated in FIG. 1, the substrate 10 includes, for example, a base 12 and a drive circuit 14. The base 12 has, for example, insulation. The drive circuit 14 drives the light emitting element 102. The drive circuit 14 includes, for example, an integrated circuit (IC).

The light emitting element 102 is mounted on the substrate 10. The light emitting element 102 is, for example, junction-down mounted. For example, a plurality of light emitting elements 102 are provided. In the example illustrated in FIG. 2, the plurality of light emitting elements 102 are arranged in a matrix in a plan view. In an example illustrated in FIG. 1, a first light emitting element 102a and a second light emitting element 102b are provided as the light emitting element 102. The first light emitting element 102a and the second light emitting element 102b are adjacent to each other. The “plan view” refers to a view from a stacking direction of a p-type semiconductor layer 22 and a light emitting layer 24 of the stacked body 20 (hereinafter also simply referred to as a “stacking direction”).

The stacked body 20 is provided between the p-electrode 30 and the n-electrode 32. The stacked body 20 includes a first taper section 20a having a taper shape increasing in width from the p-electrode 30 side toward the n-electrode 32 side. The width of the first taper section 20a gradually increases from the p-electrode 30 side toward the n-electrode 32 side. In the illustrated example, the shape of the first taper section 20a is a trapezoid. The width is size in a direction orthogonal to the stacking direction. A side surface 21 of the first taper section 20a is inclined with respect to the stacking direction. The side surface 21 of the first taper section 20a configures a side surface of the stacked body 20.

The stacked body 20 includes, for example, the p-type semiconductor layer 22, the light emitting layer 24, an n-type semiconductor layer 26, and a buffer layer 28. The p-type semiconductor layer 22, the light emitting layer 24, the n-type semiconductor layer 26, and a part of the buffer layer 28 configure the first taper section 20a. The p-type semiconductor layer 22, the light emitting layer 24, the n-type semiconductor layer 26, and the buffer layer 28 are, for example, group III nitride semiconductors and have a wurtzite type crystal structure.

The p-type semiconductor layer 22 is provided on the p-electrode 30. The p-type semiconductor layer 22 is provided between the p-electrode 30 and the light emitting layer 24. The p-type semiconductor layer 22 has a first conductivity type. The p-type semiconductor layer 22 is, for example, a p-type GaN layer doped with Mg.

The light emitting layer 24 is provided on the p-type semiconductor layer 22. The light emitting layer 24 is provided between the p-type semiconductor layer 22 and the n-type semiconductor layer 26. The light emitting layer 24 has an i-type conductivity type in which impurities are not intentionally doped. The light emitting layer 24 generates light by an electrical current being injected. The light emitting layer 24 includes, for example, a well layer and a barrier layer. The well layer and the barrier layer are i-type semiconductor layers. The well layer is, for example, an InGaN layer. The barrier layer is, for example, a GaN layer. The light emitting layer 24 has a multiple quantum well (MQW) structure including the well layer and the barrier layer.

The number of well layers and barrier layers configuring the light emitting layer 24 is not particularly limited. For example, only one well layer may be provided and, in this case, the light emitting layer 24 has a single quantum well (SQW) structure.

The n-type semiconductor layer 26 is provided on the light emitting layer 24. The n-type semiconductor layer 26 is provided between the light emitting layer 24 and the n-electrode 32. In the illustrated example, the size in the stacking direction of the n-type semiconductor layer 26 is larger than the size in the stacking direction of the p-type semiconductor layer 22. The n-type semiconductor layer 26 has a second conductivity type different from the first conductivity type. The n-type semiconductor layer 26 is, for example, an n-type GaN layer doped with Si.

The buffer layer 28 is provided on the n-type semiconductor layer 26. The buffer layer 28 is provided between the n-type semiconductor layer 26 and the n-electrode 32. The buffer layers 28 of the light emitting elements 102 adjacent to each other are continuous. In the illustrated example, the buffer layer 28 of the first light emitting element 102a and the buffer layer 28 of the second light emitting element 102b are continuous. The material of the buffer layer 28 is, for example, the same as the material of the n-type semiconductor layer 26.

The buffer layer 28 is in contact with the n-electrode 32. A plurality of protrusions 29 are provided on a contact surface of the buffer layer 28 with the n-electrode 32. The plurality of protrusions 29 are, for example, periodically provided. The height of the protrusion 29 is, for example, 400 nm or less. The interval between the distal ends of the protrusions 29 adjacent to each other is, for example, 230 nm or less. The plurality of protrusions 29 may configure a moth-eye structure. A change in a refractive index at the interface between the buffer layer 28 and the n-electrode 32 can be made gentle by the plurality of protrusions 29 in the direction from the buffer layer 28 toward the n-electrode 32. Accordingly, light reflected on the interface between the buffer layer 28 and the n-electrode 32 can be reduced. Although not illustrated, the plurality of protrusions 29 may be provided at random.

In the light emitting device 100, the p-type semiconductor layer 22, the i-type light emitting layer 24, and the n-type semiconductor layer 26 constitute a pin diode. In the light emitting device 100, when a forward bias voltage of the pin diode is applied between the p-electrode 30 and the n-electrode 32, an electric current is injected into the light emitting layer 24 and recombination of electrons and holes occurs in the light emitting layer 24. With this recombination, the light emitting layer 24 generates light.

The p-electrode 30 is provided between the substrate 10 and the stacked body 20. In the illustrated example, the p-electrode 30 is provided between the substrate 10 and the p-type semiconductor layer 22. The p-electrode 30 is electrically coupled to the p-type semiconductor layer 22. The p-type semiconductor layer 22 may be in ohmic contact with the p-electrode 30. As the p-electrode 30, for example, an electrode in which a Pd layer, a Pt layer, and an Au layer are stacked in this order from the p-type semiconductor layer 22 side is used. The p-electrode 30 reflects the light generated in the light emitting layer 24 to the n-electrode 32 side.

The p-electrode 30 is one electrode for injecting an electric current into the light emitting layer 24. For example, the potential of a data signal is applied to the p-electrode 30 from the drive circuit 14. In the plurality of light emitting elements 102, for example, the p-electrodes 30 are separated from one another.

The n-electrode 32 is provided on a side of the stacked body 20 opposite to the p-electrode 30. The n-electrode 32 is provided on the buffer layer 28. The n-electrode 32 is provided between the buffer layer 28 and the transparent layer 70. The n-electrode 32 is disposed to face the substrate 10. The n-electrode 32 is electrically coupled to the n-type semiconductor layer 26 via the buffer layer 28. The buffer layer 28 may be in ohmic contact with the n-electrode 32. The n-electrode 32 transmits the light generated in the light emitting layer 24. The light generated in the light emitting layer 24 is emitted from the n-electrode 32 side. The material of the n-electrode 32 is, for example, indium tin oxide (ITO).

The n-electrode 32 is the other electrode for injecting an electric current into the light emitting layer 24. For example, constant potential is applied to the n-electrode 32. Ground potential may be applied to the n-electrode 32. In the plurality of light emitting elements 102, the n-electrode 32 is, for example, a common electrode. In the illustrated example, the n-electrode 32 is continuous in the first light emitting element 102a and the second light emitting element 102b.

The insulating layer 40 covers the stacked body 20. The insulating layer 40 is provided on the side surface 21 of the first taper section 20a. In the illustrated example, the insulating layer 40 is further provided on the lower surface of the buffer layer 28. The insulating layers 40 of the light emitting elements 102 adjacent to each other are continuous. In the illustrated example, the insulating layer 40 of the first light emitting element 102a and the insulating layer 40 of the second light emitting element 102b are continuous. The insulating layer 40 surrounds the stacked body 20 in the plan view. The insulating layer 40 transmits the light generated in the light emitting layer 24. The insulating layer 40 is, for example, an Si O₂ layer.

A first contact hole 42 is formed in the insulating layer 40. The first contact hole 42 overlaps the p-electrode 30 in the plan view. The first contact hole 42 exposes the p-electrode 30.

The metal layer 50 is provided on the insulating layer 40. The metal layer 50 is located on a side of the stacked body 20. In the illustrated example, the metal layer 50 is further provided in the first contact hole 42. The metal layer 50 is in contact with the p-electrode 30. In the light emitting elements 102 adjacent to each other, metal layers 50 are separated from each other. The metal layer 50 surrounds the stacked body 20 in the plan view. The metal layer 50 is, for example, an Au layer or an Al layer. The metal layer 50 reflects the light generated in the light emitting layer 24 toward the stacked body 20 side.

The interlayer insulating layer 60 covers the light emitting element 102. The interlayer insulating layer 60 surrounds the first taper section 20a in the plan view. The interlayer insulating layer 60 is provided between the substrate 10 and the n-electrode 32. The interlayer insulating layer 60 is, for example, an Si O₂ layer.

A second contact hole 62 is formed in the interlayer insulating layer 60. The second contact hole 62 overlaps the first contact hole 42 in the plan view. The second contact hole 62 exposes the metal layer 50. The metal layer 50 exposed by the second contact hole 62 is electrically coupled to the drive circuit 14 via a contact 64. The contact 64 includes, for example, a first portion 64a surrounded by the interlayer insulating layer 60 in the plan view and a second portion 64b surrounded by the base 12. The material of the contact 64 is, for example, Cu.

The transparent layer 70 is provided on a side of the n-electrode 32 opposite to the stacked body 20. The transparent layer 70 is provided on the n-electrode 32. The transparent layer 70 is provided between the n-electrode 32 and the lens 90. The transparent layer 70 transmits the light generated in the light emitting layer 24. The thickness of the transparent layer 70 is, for example, 0.5 μm or more and 2.0 μm or less and is preferably 0.7 μm or more and 1.5 μm or less. If the thickness of the transparent layer 70 is 0.5 μm or more, the transparent layer 70 can function as an etching stopper when etching the reflective member 80. If the thickness of the transparent layer 70 is 2.0 μm or less, the light generated in the light emitting layer 24 can be efficiently made incident on the lens 90.

The transparent layer 70 may have insulation. When the transparent layer 70 has insulation, the transparent layer 70 is, for example, an Si O₂ layer, an SiON layer, or an SiN layer. The transparent layer 70 may have electric conductivity. When the transparent layer 70 has the electric conductivity, the transparent layer 70 is, for example, an indium zinc oxide (IZO) layer or an ITO layer.

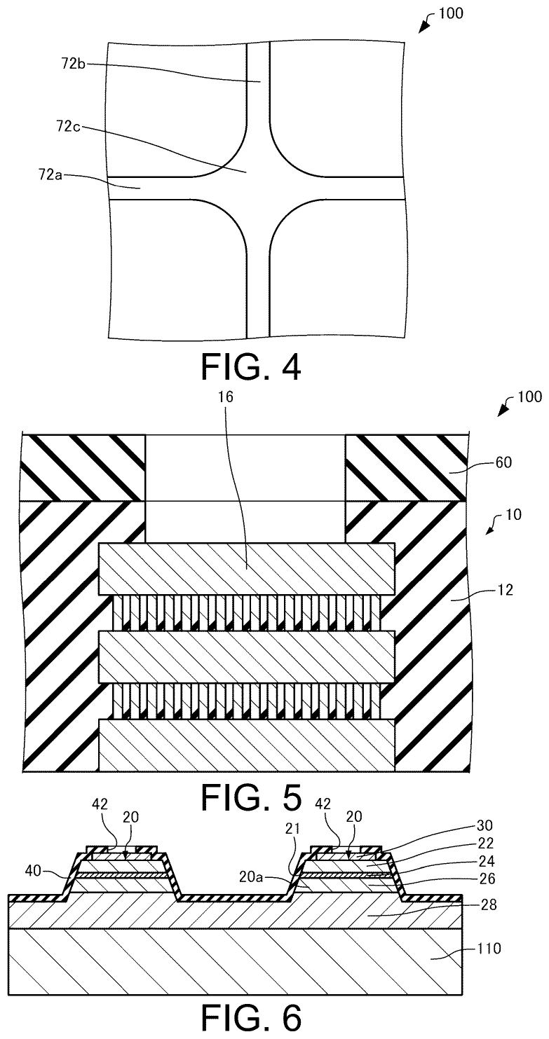

A third contact hole 72 is formed in the transparent layer 70. The third contact hole 72 exposes the n-electrode 32. In the third contact hole 72, the reflective member 80 is in contact with the n-electrode 32. In the example illustrated in FIG. 2, the third contact hole 72 includes a plurality of first extending sections 72a extending in a first direction and a plurality of second extending sections 72b extending in a second direction orthogonal to the first direction. In the plan view, the first taper section 20a and the p-electrode 30 are surrounded by the third contact hole 72. In the illustrated example, the width of an intersection 72c of the first extending section 72a and the second extending section 72b is the same as the width of the extending sections 72a and 72b. As illustrated in FIG. 3, the width of the intersection 72c may be larger than the width of the extending sections 72a and 72b. Accordingly, contact resistance between the n-electrode 32 and the reflective member 80 can be reduced. As illustrated in FIG. 4, the intersection 72c may have an arc corresponding to the shape of the emission surface 92 of the lens 90.

As illustrated in FIG. 1, the reflective member 80 is provided on the n-electrode 32 and the transparent layer 70. The reflective member 80 is provided on a side of the lens 90 and the transparent layer 70. The reflective member 80 surrounds the lens 90 in the plan view. The reflective member 80 is provided to be in contact with the third contact hole 72. The reflective member 80 is electrically coupled to the n-electrode 32 in the third contact hole 72. The reflective member 80 does not overlap the light emitting layer 24 in the plan view. The reflective member 80 reflects the light generated in the light emitting layer 24 toward the emission surface 92 of the lens 90.

The reflective member 80 is made of metal. That is, the material of the reflective member 80 is metal. The reflective member 80 includes, for example, a first layer 82, a second layer 84, and a third layer 86. The first layer 82 is provided on the n-electrode 32. The first layer 82 is provided between the n-electrode 32 and the second layer 84. The first layer 82 is, for example, a TiN layer. The first layer 82 improves adhesion between the n-electrode 32 and the reflective member 80. The second layer 84 is provided on the first layer 82. The second layer 84 is provided between the first layer 82 and the third layer 86. The thickness of the second layer 84 is larger than the thickness of the first layer 82 and the thickness of the third layer 86. The reflectance of the second layer 84 to the light generated in the light emitting layer 24 is higher than the reflectance of the first layer 82 and the reflectance of the third layer 86 to the light generated in the light emitting layer 24. The second layer 84 is, for example, an Al layer. The third layer 86 is provided on the second layer 84. The thirty-third layer 86 is, for example, a TiN layer. The thirty-third layer 86 reduces reflection of light from an exposure device by the reflective member 80 when the reflective member 80 is patterned using photolithography.

The reflective member 80 is electrically coupled to the drive circuit 14. As illustrated in FIG. 5, the substrate 10 includes, for example, a pad 16. The pad 16 is electrically coupled to the drive circuit 14. The pad 16 is electrically coupled to the reflective member 80 via, for example, not-illustrated wire bonding.

As illustrated in FIG. 1, the lens 90 is provided on a side of the transparent layer 70 opposite to the n-electrode 32. The lens 90 is provided on the transparent layer 70. The lens 90 overlaps the light emitting layer 24 in the plan view. A plurality of lenses 90 are provided to correspond to the plurality of light emitting elements 102. The plurality of lenses 90 configure a microlens array. The material of the lens 90 is, for example, SiON.

The lens 90 includes, for example, an emission surface 92 and a second taper section 94. The emission surface 92 emits the light generated in the light emitting layer 24. The emission surface 92 is a curved surface. In the illustrated example, the emission surface 92 is a convex surface. The second taper section 94 has a taper shape, the width of which increases from the transparent layer 70 side toward the emission surface 92 side. The width of the second taper section 94 gradually increases from the transparent layer 70 side toward the emission surface 92 side. In the illustrated example, the shape of the second taper section 94 is a trapezoid. The reflective member 80 is in contact with a side surface 95 of the second taper section 94. The side surface 95 is inclined with respect to the stacking direction. The side surface 21 of the first taper section 20a and the side surface 95 of the second taper section 94 may be present on the same imaginary plane.

In the above explanation, a semiconductor layer provided between the substrate 10 and the light emitting layer 24 is a p-type semiconductor layer and a semiconductor layer provided on the side of the light emitting layer 24 opposite to the substrate 10 is an n-type semiconductor layer. However, the p-type and the n-type may be opposite. That is, the semiconductor layer provided between the substrate 10 and the light emitting layer 24 may be the n-type semiconductor layer and the semiconductor layer provided on the side of the light emitting layer 24 opposite to the substrate 10 may be the p-type semiconductor layer. In this case, an electrode electrically coupled to the semiconductor layer provided between the substrate 10 and the light emitting layer 24 is an n-electrode and an electrode electrically coupled to the semiconductor layer provided on the side of the light emitting layer 24 opposite to the substrate 10 is a p-electrode.

Although the InGaN-based light emitting layer 24 is explained above, as the light emitting layer 24, according to a wavelength of emitted light, various material-based light emitting layers capable of emitting light by an electric current being injected can be used. Semiconductor material-based such as AlGaN-based, AlGaAs-based, InGaAs-based, InGaAsP-based, InP-based, GaP-based, and AlGaP-based light emitting layers can be used.

### 1.2. Manufacturing Method for the Light Emitting Device

Subsequently, a manufacturing method for the light emitting device 100 according to the first embodiment is explained with reference to the drawings. FIGS. 6 to 14 are cross-sectional views schematically illustrating a manufacturing process for the light emitting device 100 according to the first embodiment.

As illustrated in FIG. 6, the buffer layer 28, the n-type semiconductor layer 26, the light emitting layer 24, and the p-type semiconductor layer 22 are epitaxially grown in this order on a growth substrate 110. Examples of a method for epitaxial growth include metal organic chemical vapor deposition (MOCVD) and molecular beam epitaxy (MBE). The growth substrate 110 is a substrate for epitaxially growing the stacked body 20. The growth substrate 110 is, for example, a silicon substrate. The stacked body 20 is formed by this step.

Subsequently, the p-electrode 30 is formed at the stacked body 20. The p-electrode 30 is formed by, for example, a vacuum deposition method, a sputtering method, or a chemical vapor deposition (CVD) method.

Subsequently, the stacked body 20 is patterned. The patterning is performed such that the side surface 21 of the first taper section 20a of the stacked body 20 is inclined with respect to the stacking direction. The patterning is performed by, for example, photolithography and dry etching.

Subsequently, the insulating layer 40 is formed at the stacked body 20. The insulating layer 40 is formed by, for example, the CVD method or an atomic layer deposition (ALD) method.

Subsequently, the insulating layer 40 is patterned to form the first contact hole 42. Accordingly, the p-electrode 30 is exposed.

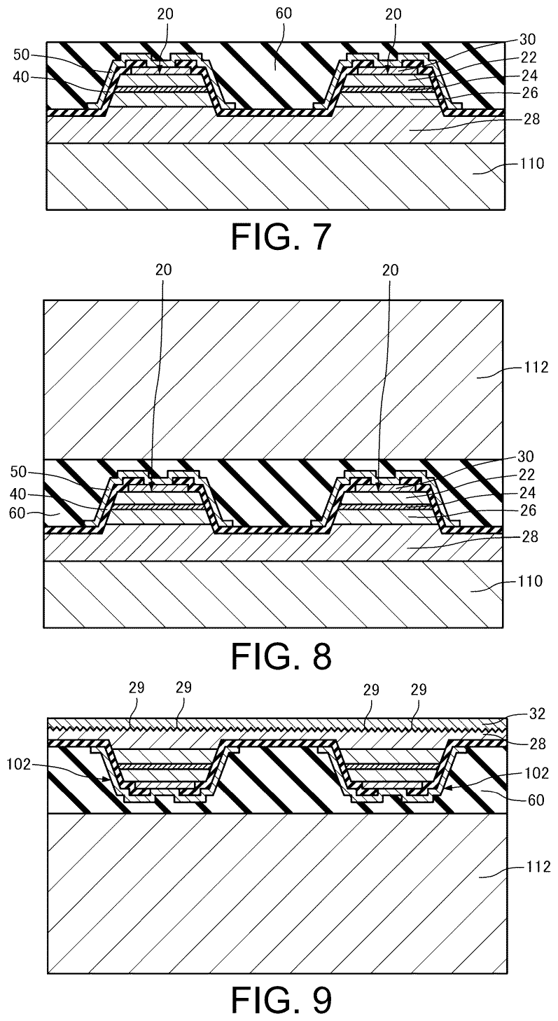

As illustrated in FIG. 7, the metal layer 50 is formed at the p-electrode 30 and on the insulating layer 40. The metal layer 50 is formed by, for example, the vacuum deposition method or the sputtering method.

Subsequently, the interlayer insulating layer 60 is formed to cover the stacked body 20. The interlayer insulating layer 60 is formed by, for example, the CVD method or a spin coat method. The interlayer insulating layer 60 is planarized using a chemical mechanical polishing (CMP) device or the like.

As illustrated in FIG. 8, a first support substrate 112 is pasted to the interlayer insulating layer 60. The first support substrate 112 is pasted such that the stacked body 20 is located between the first support substrate 112 and the growth substrate 110.

As illustrated in FIG. 9, the growth substrate 110 and a part of the buffer layer 28 are removed. The growth substrate 110 and the buffer layer 28 are removed by, for example, etching or CMP. FIG. 9 illustrates an upside down state with respect to the state illustrated in FIG. 8.

Subsequently, the plurality of protrusions 29 are formed at the buffer layer 28. The protrusions 29 are formed by, for example, photolithography and etching.

Subsequently, the n-electrode 32 is formed at the buffer layer 28. The n-electrode 32 is formed by, for example, the vacuum deposition method or the sputtering method. The plurality of light emitting elements 102 are formed by this step.

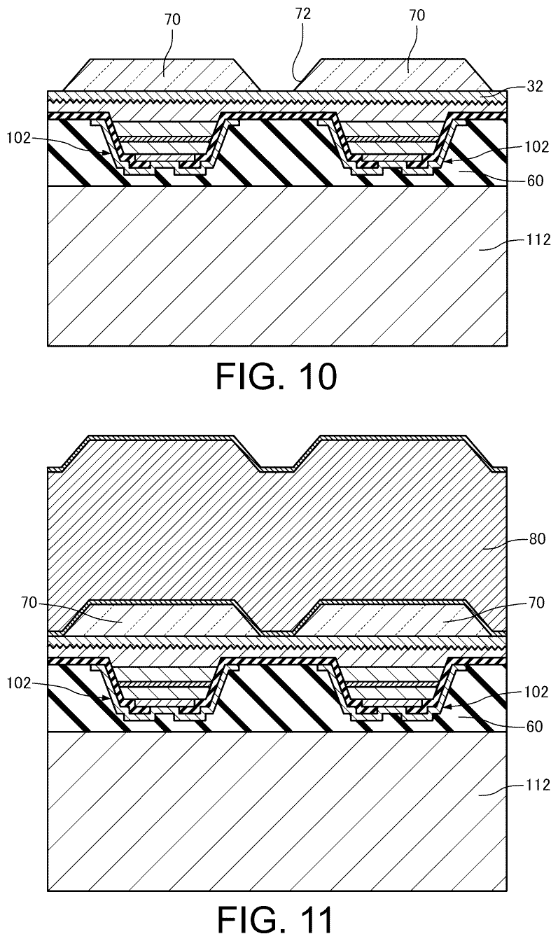

As illustrated in FIG. 10, the transparent layer 70 is formed at the n-electrode 32. The transparent layer 70 is formed by, for example, the CVD method. Subsequently, the transparent layer 70 is patterned to form the third contact hole 72. Accordingly, the n-electrode 32 is exposed.

As illustrated in FIG. 11, the reflective member 80 is formed at the entire surface. The reflective member 80 is formed by, for example, the sputtering method or the vacuum deposition method.

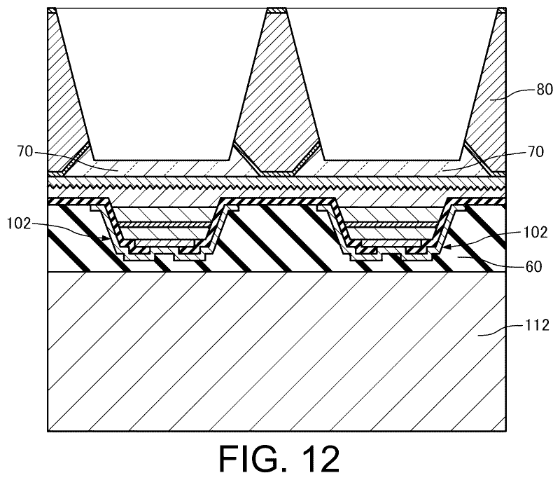

As illustrated in FIG. 12, the reflective member 80 is patterned. The patterning is performed by, for example, photolithography and etching. Accordingly, the transparent layer 70 is exposed. If the reflective member remains at a position overlapping the light emitting layer in the plan view, light generated in the light emitting layer cannot be emitted upward. For that reason, the reflective member 80 is over-etched considering manufacturing variations and the like. Accordingly, a part of the transparent layer 70 is removed. The transparent layer 70 functions as an etching stopper in the etching of the reflective member 80. The transparent layer 70 is a sacrificial layer. In the etching of the reflective member 80, the n-electrode 32 is not exposed. The etching is performed such that a side surface of the reflective member 80 is inclined with respect to the stacking direction.

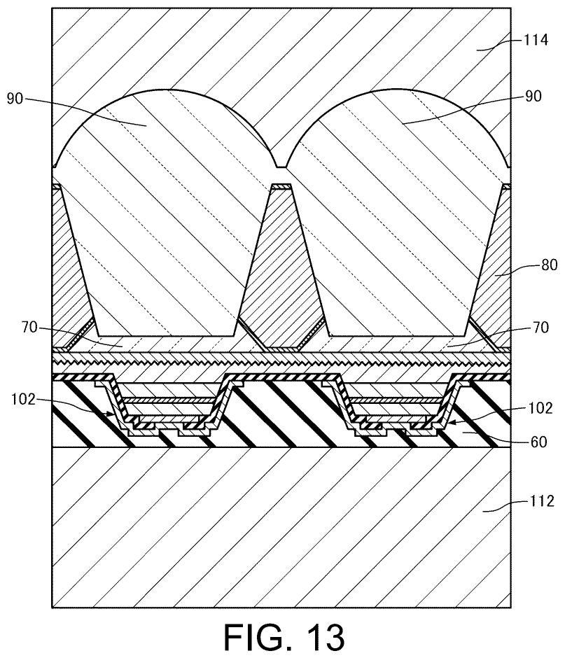

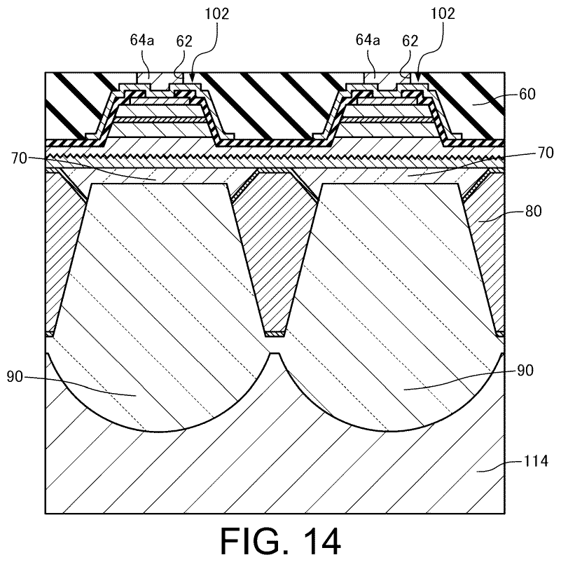

As illustrated in FIG. 13, the lens 90 in contact with the reflective member 80 is formed at the transparent layer 70. The lens 90 is formed by photolithography and dry etching, for example, after SiON is deposited by the CVD method. Subsequently, a second support substrate 114 is formed at the lens 90.

As illustrated in FIG. 14, the first support substrate 112 is removed. FIG. 14 illustrates an upside down state with respect to the state illustrated in FIG. 13.

Subsequently, the interlayer insulating layer 60 is patterned to form the second contact hole 62. Accordingly, the metal layer 50 is exposed.

Subsequently, the first portion 64a of the contact 64 is formed in the second contact hole 62.

As illustrated in FIG. 1, the substrate 10 is prepared and the first portion 64a of the contact 64 and the second portion 64b of the contact 64 are joined. Accordingly, the light emitting element 102 can be junction-mounted on the substrate 10. The light emitting element 102 is, for example, joined to the substrate 10 by hybrid bonding. FIG. 1 illustrates an upside down state with respect to the state illustrated in FIG. 14.

Subsequently, the second support substrate 114 is removed.

The light emitting device 100 can be manufactured by the process explained above.

### 1.3. Action Effects

In the light emitting device 100, the first light emitting element 102a includes the stacked body 20 serving as the first stacked body including the p-type semiconductor layer 22 serving as the first semiconductor layer, the n-type semiconductor layer 26 serving as the second semiconductor layer, and the light emitting layer 24 serving as the first light emitting layer, the insulating layer 40 serving as the first insulating layer provided on the side surface 21 of the stacked body 20, the metal layer 50 serving as the first metal layer provided on the insulating layer 40 and located on the side of the stacked body 20, the p-electrode 30 serving the first electrode provided between the substrate 10 and the stacked body 20 and electrically coupled to the p-type semiconductor layer 22, and the n-electrode 32 serving as the second electrode provided on the side of the stacked body 20 opposite to the p-electrode 30 and electrically coupled to the n-type semiconductor layer 26. The light emitting device 100 further includes the transparent layer 70 serving as the first transparent layer provided on the side of the n-electrode 32 of the first light emitting element 102a opposite to the stacked body 20, the lens 90 serving as the first lens provided on the side of the transparent layer 70 opposite to the n-electrode 32 and overlapping the light emitting layer 24 in the plan view, and the reflective member 80 made of metal provided on the side of the lens 90 and the transparent layer 70. The reflective member 80 is electrically coupled to the n-electrode 32.

For that reason, in the light emitting device 100, when the reflective member 80 is patterned using etching, the possibility of the n-electrode 32 being etched can be reduced by the transparent layer 70, and the possibility of disconnection and an increase in resistance can be reduced. Furthermore, in the light emitting device 100, since the reflective member 80 is electrically coupled to the n-electrode 32, an electric current injected into the light emitting layer 24 can be increased and an amount of the light generated in the light emitting layer 24 can be increased. Accordingly, it is possible to achieve an increase in luminance and an increase in efficiency. If the n-electrode is thickened in order to prevent disconnection and the like, crosstalk between the first light emitting element and the second light emitting element increases. However, in the light emitting device 100, since the transparent layer 70 is provided and the reflective member 80 is electrically coupled to the n-electrode 32, it is possible to reduce crosstalk between the first light emitting element 102a and the second light emitting element 102b while suppressing disconnection and the like.

In the light emitting device 100, the second light emitting element 102b includes the stacked body 20 serving as the second stacked body including the p-type semiconductor layer 22 serving as the third semiconductor layer, the n-type semiconductor layer 26 serving as the fourth semiconductor layer, and the light emitting layer 24 serving as the second light emitting layer, the insulating layer 40 serving as the second insulating layer provided on the side surface 21 of the stacked body 20, the metal layer 50 serving as the second metal layer provided on the insulating layer 40 and located on the side of the stacked body 20, the p-electrode 30 serving as the third electrode provided between the substrate 10 and the stacked body 20 and electrically coupled to the p-type semiconductor layer 22, and the n-electrode 32 serving as the fourth electrode provided on the side of the stacked body 20 opposite to the p-electrode 30 and electrically coupled to the n-type semiconductor layer 26. The light emitting device 100 further includes the transparent layer 70 serving the second transparent layer provided on the side of the n-electrode 32 of the second light emitting element 102b opposite to the stacked body 20 and the lens 90 serving as the second lens provided on the side of the transparent layer 70 opposite to the n-electrode 32 and overlapping the light emitting layer 24 in the plan view. The n-electrode 32 of the first light emitting element 102a and the n-electrode 32 of the second light emitting element 102b are continuous. For that reason, in the light emitting device 100, the n-electrode 32 of the first light emitting element 102a and the n-electrode 32 of the second light emitting element 102b can be integrally formed and the n-electrode 32 can be used as a common electrode in the first light emitting element 102a and the second light emitting element 102b.

In the light emitting device 100, the insulating layer 40 of the first light emitting element 102a and the insulating layer 40 of the second light emitting element 102b are continuous. For that reason, in the light emitting device 100, the insulating layer 40 of the first light emitting element 102a and the insulating layer 40 of the second light emitting element 102b can be integrally formed.

In the light emitting device 100, the stacked body 20 includes the first taper section 20a, the width of which increases from the p-electrode 30 side toward the n-electrode 32 side, and the insulating layer 40 is provided on the side surface 21 of the first taper section 20a. For that reason, in the light emitting device 100, the light generated in the light emitting layer 24 can be reflected on the side surface 21 toward the n-electrode 32 side.

In the light emitting device 100, the lens 90 includes the emission surface 92 that emits the light generated in the light emitting layer 24 and the second taper section 94, the width of which increases from the transparent layer 70 side toward the emission surface 92 side, and the reflective member 80 is in contact with the side surface 95 of the second taper section 94. For that reason, in the light emitting device 100, the light generated in the light emitting layer 24 can be reflected on the side surface 95 toward the emission surface 92 side.

In the light emitting device 100, the emission surface 92 is a curved surface. For that reason, in the light emitting device 100, for example, the light generated in the light emitting layer 24 can be collected.

In the light emitting device 100, the transparent layer 70 may have insulation. If the transparent layer 70 has insulation, when the reflective member 80 is patterned using etching, the transparent layer 70 can be formed of a material having a rate for the etching smaller than a rate for etching for the n-electrode 32. That is, selectivity of the reflective member 80 and the transparent layer 70 with respect to etching can be increased. Accordingly, the possibility of the n-electrode 32 being etched at the time of the patterning of the reflective member 80 can be further reduced.

In the light emitting device 100, the transparent layer 70 may have electric conductivity. If the transparent layer 70 has electric conductivity, resistance can be reduced and an electric current injected into the light emitting layer 24 can be further increased.

### 2. Second Embodiment

### 2.1. Light Emitting Device

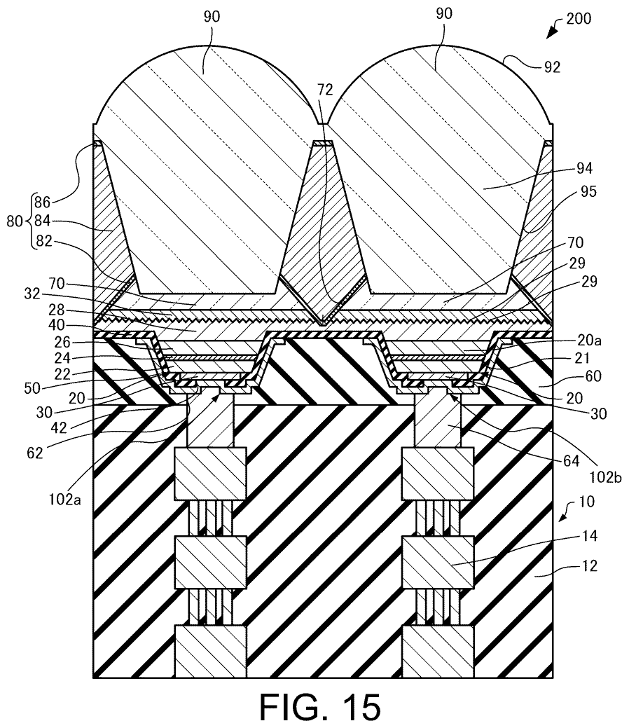

Subsequently, a light emitting device according to a second embodiment is explained with reference to the drawings. FIG. 15 is a cross-sectional view schematically illustrating a light emitting device 200 according to the second embodiment. Hereinafter, in the light emitting device 200 according to the second embodiment, members having the same functions as the functions of the constituent members of the light emitting device 100 according to the first embodiment explained above are denoted by the same reference numerals and signs and detailed explanation of the members is omitted.

In the light emitting device 100 explained above, as illustrated in FIG. 1, the reflective member 80 is separated from the buffer layer 28.

In contrast, in the light emitting device 200, the reflective member 80 is in contact with the buffer layer 28 as illustrated in FIG. 15. That is, the reflective member 80 is in contact with the stacked body 20. The third contact hole 72 penetrates the n-electrode 32 and exposes the buffer layer 28.

In the light emitting device 200, since the reflective member 80 is in contact with the buffer layer 28, the lower end of the reflecting member 80 can be located lower. That is, the distance between the reflective member 80 and the light emitting layer 24 can be reduced. Accordingly, crosstalk between the first light emitting element 102a and the second light emitting element 102b can be reduced.

### 2.2. Light Emitting Device

Subsequently, a manufacturing method for the light emitting device 200 according to the second embodiment is explained. The manufacturing method for the light emitting device 200 according to the second embodiment is basically the same as the manufacturing method for the light emitting device 100 according to the first embodiment explained above except that the third contact hole 72 is formed such that the buffer layer 28 is exposed. Therefore, detailed explanation of the manufacturing method is omitted.

### 3. Third Embodiment

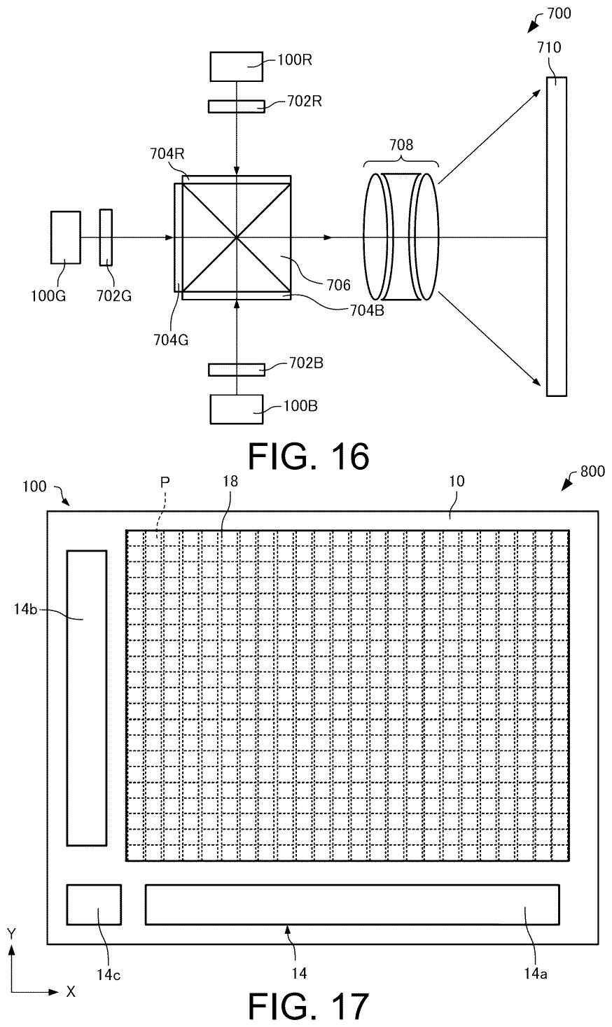

Subsequently, a projector serving as electronic equipment according to a third embodiment is explained with reference to the drawings. FIG. 16 is a diagram schematically illustrating a projector 700 according to the third embodiment.

The projector 700 includes, for example, the light emitting device 100 as a light source. In FIG. 16, for convenience, the light emitting device 100 is simplified and illustrated.

The projector 700 includes a not-illustrated housing and a red light source 100R, a green light source 100G, and a blue light source 100B that are provided in the housing and respectively emit red light, green light, and blue light. For convenience, in FIG. 16, the red light source 100R, the green light source 100G, and the blue light source 100B are simplified and illustrated.

The projector 700 further includes, for example, a first optical element 702R, a second optical element 702G, a third optical element 702B, a first light modulation device 704R, a second light modulation device 704G, a third light modulation device 704B, and a projection device 708 provided in the housing. The first light modulation device 704R, the second light modulation device 704G, and the third light modulation device 704B are, for example, transmissive liquid crystal light valves. The projection device 708 is, for example, a projection lens.

Light emitted from the red light source 100R is made incident on the first optical element 702R. Light emitted from the red light source 100R is collected by the first optical element 702R. The first optical element 702R may have functions than the light collection. The second optical element 702G and the third optical element 702B may also have functions other than the light collection.

The light collected by the first optical element 702R is made incident on the first light modulation device 704R. The first light modulation device 704R modulates the incident light according to image information. Then, the projection device 708 enlarges an image formed by the first light modulation device 704R and projects the image onto a screen 710.

Light emitted from the green light source 100G is made incident on the second optical element 702G. Light emitted from the green light source 100G is collected by the second optical element 702G.

The light collected by the second optical element 702G is made incident on the second light modulation device 704G. The second light modulation device 704G modulates the incident light according to the image information. Then, the projection device 708 enlarges an image formed by the second light modulation device 704G and projects the image onto the screen 710.

Light emitted from the blue light source 100B is made incident on the third optical element 702B. Light emitted from the blue light source 100B is collected by the third optical element 702B.

The light collected by the third optical element 702B is made incident on the third light modulation device 704B. The third light modulation device 704B modulates the incident light according to image information. Then, the projection device 708 enlarges an image formed by the third light modulation device 704B and projects the image onto the screen 710.

The projector 700 further includes, for example, a cross dichroic prism 706 that combines the lights emitted from the first light modulation device 704R, the second light modulation device 704G, and the third light modulation device 704B and guides the combined light to the projection device 708.

Three color lights modulated by the first light modulation device 704R, the second light modulation device 704G, and the third light modulation device 704B are made incident on the cross dichroic prism 706. The cross dichroic prism 706 is formed by pasting together four rectangular prisms. A dielectric multilayer film for reflecting red light and a dielectric multilayer film for reflecting blue light are disposed on the inner surface of the cross dichroic prism 706. The three colored lights are combined by these dielectric multilayer films and light representing a color image is formed. Then, the combined light is projected onto the screen 710 by the projection device 708 and an enlarged image is displayed.

The red light source 100R, the green light source 100G, and the blue light source 100B may control the light emitting device 100 as pixels of videos according to image information to directly form the videos without using the first light modulation device 704R, the second light modulation device 704G, and the third light modulation device 704B. Then, the projection device 708 may enlarge the videos formed by the red light source 100R, the green light source 100G, and the blue light source 100B and project the videos onto the screen 710.

Although the transmissive liquid crystal light valves are used as the light modulation devices in the example explained above, a light valve other than liquid crystal light valve may be used or a reflective light valve may be used. Examples of the light valve explained above include a reflective liquid crystal light valve and a digital micromirror device. A configuration of the projection device is changed as appropriate according to a type of a light valve in use.

The light source can also be applied to a light source device of a scanning image display device including scanning means that is an image forming device that causes light from the light source to scan on a screen to thereby cause a display surface to display an image having a desired size.

### 4. Fourth Embodiment

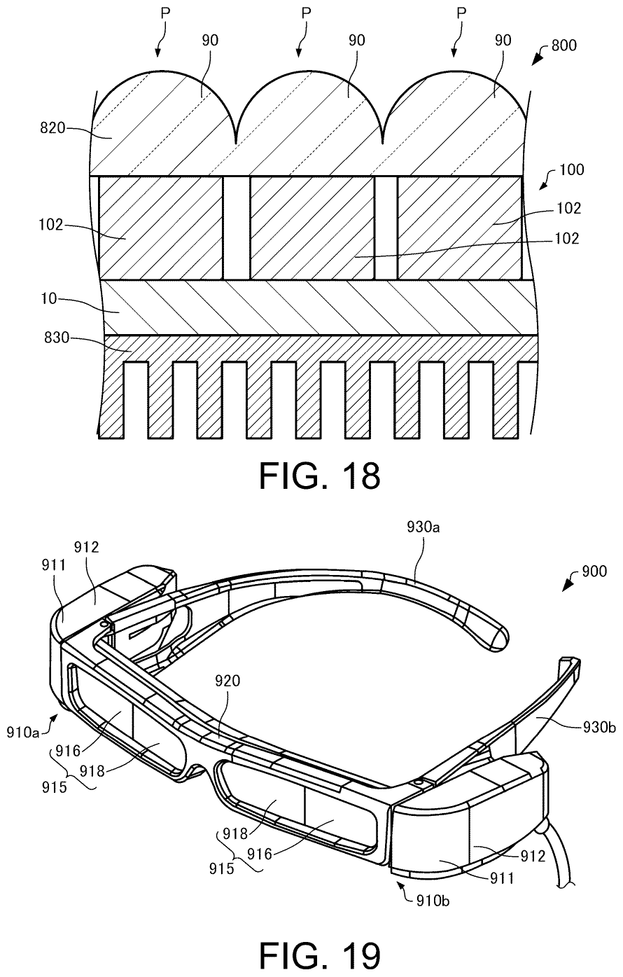

Subsequently, a display serving as electronic equipment according to a fourth embodiment is explained with reference to the drawings. FIG. 17 is a plan view schematically illustrating a display 800 according to the fourth embodiment. FIG. 18 is a cross-sectional view schematically illustrating the display 800 according to the fourth embodiment. In FIG. 17, an X axis and a Y axis are illustrated as two axes orthogonal to each other. For convenience, in FIG. 17 and FIG. 18, the light emitting device 100 is simplified and illustrated.

The display 800 includes, for example, the light emitting device 100 as a light source. For convenience, in FIG. 17 and FIG. 18, the light emitting device 100 is simplified and illustrated.

The display 800 is a display device that displays an image. The image includes an image in which only character information is displayed. The display 800 is a self-luminous display. As illustrated in FIGS. 17 and 18, the display 800 includes, for example, a lens array 820 and a heat sink 830.

The drive circuit 14 drives the light emitting element 102 based on, for example, input image information. The substrate 10 includes, for example, a display region 18. The drive circuit 14 includes, for example, a data line drive circuit 14a, a scanning line drive circuit 14b, and a control circuit 14c.

The display region 18 includes a plurality of pixels P. In the illustrated example, the pixels P are arrayed along the X axis and the Y axis.

Although not illustrated, a plurality of scanning lines and a plurality of data lines are provided on the substrate 10. For example, the scanning lines extend along the X axis and the data lines extend along the Y axis. The scanning lines are coupled to the scanning line drive circuit 14b. The data lines are coupled to the data line drive circuit 14a. The pixels P are provided to correspond to intersections of the scanning lines and the data lines.

One pixel P includes, for example, one light emitting element 102, one lens 90, and a not-illustrated pixel circuit. The pixel circuit includes a switching transistor that functions as a switch of the pixel P. A gate of the switching transistor is coupled to the scanning lines and one of a source and a drain of the switching transistor is coupled to the data lines.

The data line drive circuit 14a and the scanning line drive circuit 14b are circuits that control driving of the light emitting elements 102 configuring the pixels P. The control circuit 14c controls display of an image.

Image data is supplied to the control circuit 14c from an upper circuit. The control circuit 14c supplies various signals based on the image data to the data line drive circuit 14a and the scanning line drive circuit 14b.

When a scanning line is selected by the scanning line drive circuit 14b activating a scanning signal, a switching transistor of the selected pixel P is turned on. At this time, the data line drive circuit 14a supplies a data signal to the selected pixel P from the data lines, whereby the light emitting element 102 of the selected pixel P emits light according to the data signal.

The lens array 820 includes a plurality of lenses 90. The heat sink 830 is in contact with the substrate 10. The material of the heat sink 830 is metal such as copper or aluminum. The heat sink 830 dissipates heat generated in the light emitting element 102.

### 5. Fifth Embodiment

### 5.1. Overall Configuration

Subsequently, a head-mounted display serving as electronic equipment according to a fifth embodiment is explained with reference to the drawings. FIG. 19 is a perspective view schematically illustrating a head-mounted display 900 according to the fifth embodiment.

As illustrated in FIG. 19, the head-mounted display 900 is a head-mounting type display having an appearance like glasses. The head-mounted display 900 is worn on the head of an observer. The observer means a user who uses the head-mounted display 900. The head-mounted display 900 can cause the observer to visually recognize video light by a virtual image and visually recognize an outside world image see-through.

The head-mounted display 900 includes, for example, a first display unit 910a, a second display unit 910b, a frame 920, a first temple 930a, and a second temple 930b.

The first display unit 910a and the second display unit 910b display images. Specifically, the first display unit 910a displays a virtual image for the right eye of the observer. The second display unit 910b displays a virtual image for the left eye of the observer. The display units 910a and 910b include, for example, image forming devices 911 and light guide devices 915.

The image forming device 911 forms video light. The image forming device 911 includes, for example, optical systems such as light sources and projection devices and an external member 912. The external member 912 houses the light source and the projection device.

The light guide device 915 covers the front of the eyes of the observer. The light guide device 915 guides video light formed by the image forming device 911 and causes the observer to visually recognize the outside world light and the video light in an overlapping manner. Details of the image forming device 911 and the light guide device 915 are explained below.

The frame 920 supports the first display unit 910a and the second display unit 910b. The frame 920 surrounds, for example, the display units 910a and 910b. In the illustrated example, the image forming device 911 of the first display unit 910a is attached to one end portion of the frame 920. The image forming device 911 of the second display unit 910b is attached to the other end portion of the frame 920.

The first temple 930a and the second temple 930b extend from the frame 920. In the illustrated example, the first temple 930a extends from one end portion of the frame 920. The second temple 930b extends from the other end portion of the frame 920.

The first temple 930a and the second temple 930b are suspended on the ears of the observer when the head-mounted display 900 is worn by the observer. The head of the observer is located between the temples 930a and 930b.

### 5.2. Image Forming Device and Light Guide Device

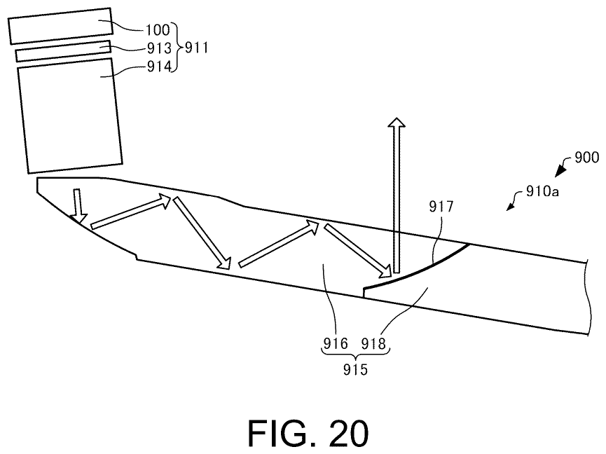

FIG. 20 is a diagram schematically illustrating the image forming device 911 and the light guide device 915 of the first display unit 910a of the head-mounted display 900. The first display unit 910a and the second display unit 910b basically have the same configuration. Therefore, the following explanation of the first display unit 910a can be applied to the second display unit 910b.

As illustrated in FIG. 20, the image forming device 911 includes, for example, the light emitting device 100 serving as the light source, a light modulation device 913, and a projection device 914 for image formation. For convenience, in FIG. 20, the light emitting device 100 is simplified and illustrated.

The light modulation device 913 modulates light made incident from the light emitting device 100 according to image information and emits video light. The light modulation device 913 is a transmissive liquid crystal light valve. The light emitting device 100 may be a self-luminous light emitting device that emits light according to input image information. In this case, the light modulation device 913 is not provided.

The projection device 914 projects the video light emitted from the light modulation device 913 toward the light guide device 915. The projection device 914 is, for example, a projection lens. As the lens configuring the projection device 914, a lens having an axisymmetric plane as a lens surface may be used.

The light guide device 915 is accurately positioned with respect to the projection device 914 by, for example, being screwed to a lens barrel of the projection device 914. The light guide device 915 includes, for example, a video light guide member 916 that guides video light and a transparent member 918 for see-through.

The video light emitted from the projection device 914 is made incident on the video light guide member 916. The video light guide member 916 is a prism that guides the video light toward the eyes of the observer. The video light made incident on the video light guide member 916 is repeatedly reflected on the inner surface of the video light guide member 916 and thereafter reflected by a reflection layer 917, and is emitted from the video light guide member 916. The video light emitted from the video light guide member 916 reaches the eyes of the observer. The reflection layer 917 is formed of, for example, metal or a dielectric multilayer film. The reflection layer 917 may be a half mirror.

The transparent member 918 is adjacent to the video light guide member 916. The transparent member 918 is fixed to the video light guide member 916. The outer surface of the transparent member 918 is, for example, continuous to the outer surface of the video light guide member 916. The transparent member 918 causes the observer to see through outside world light. Besides the function of guiding the video light, the video light guide member 916 also has a function of causing the observer to see through the outside world light. The head-mounted display 900 may have a configuration that does not cause the observer to see through the outside world light.

The light emitting device according to the embodiment explained above can also be used in a device other than the projector, the display, and the head-mounted display. The light emitting device according to the embodiment explained above is used for, for example, indoor and outdoor lighting, a laser printer, a scanner, a sensing device using light, an electronic view finder (EVF), a wearable display such as a smart watch, an in-vehicle light, and an in-vehicle head-up display.

The embodiments and the modifications explained above are examples and are not limited thereto. For example, the embodiments and the modifications can also be combined as appropriate.

The present disclosure includes substantially the same configurations as the configurations explained in the embodiments, for example, configurations having the same functions, methods, and results or configurations having the same objects and effects. The present disclosure includes configurations in which non-essential portions of the configurations explained in the embodiments are replaced. The present disclosure includes configurations that achieve the same functions and effects or configurations that can achieve the same objects as the configurations explained in the embodiments. The present disclosure includes configurations obtained by adding publicly-known techniques to the configurations explained in the embodiments.

The following contents are derived from the embodiments and the modifications explained above.

According to an aspect, there is provided a light emitting device including:
a substrate;
a first stacked body including a first semiconductor layer of a first conductivity type, a second semiconductor layer of a second conductivity type different from the first conductivity type, and a first light emitting layer provided between the first semiconductor layer and the second semiconductor layer;
a first insulating layer provided on a side surface of the first stacked body;
a first metal layer provided on the first insulating layer and located on a side of the first stacked body;
a first electrode provided between the substrate and the first stacked body and electrically coupled to the first semiconductor layer;
a second electrode provided on a side of the first stacked body opposite to the first electrode and electrically coupled to the second semiconductor layer;
a first transparent layer provided on a side of the second electrode opposite to the first stacked body;
a first lens provided on a side of the first transparent layer opposite to the second electrode and overlapping the first light emitting layer in a plan view; and
a reflective member made of metal provided on sides of the first lens and the first transparent layer, wherein
the reflective member is electrically coupled to the second electrode.

With the light emitting device, it is possible to reduce the possibility of disconnection of an electric wire and an increase in resistance.

In the light emitting device according to the aspect,
the light emitting device may include:
a second stacked body including a third semiconductor layer of the first conductivity type, a fourth semiconductor layer of the second conductivity type, and a second light emitting layer provided between the third semiconductor layer and the fourth semiconductor layer;
a second insulating layer provided on a side surface of the second stacked body;
a second metal layer provided on the second insulating layer and located on a side of the second stacked body;
a third electrode provided between the substrate and the second stacked body and electrically coupled to the third semiconductor layer;
a fourth electrode provided on a side of the second stacked body opposite to the third electrode and electrically coupled to the fourth semiconductor layer;
a second transparent layer provided on a side of the fourth electrode opposite to the second stacked body; and
a second lens provided on a side of the second transparent layer opposite to the fourth electrode and overlapping the second light emitting layer in the plan view, and
the second electrode and the fourth electrode may be continuous.

With the light emitting device, the second electrode and the fourth electrode can be integrally formed.

In the light emitting device according to the aspect, the first insulating layer and the second insulating layer may be continuous.

With the light emitting device, the first insulating layer and the second insulating layer can be integrally formed.

In the light emitting device according to the aspect,
the first stacked body may include a first taper section, width of which increases from the first electrode side toward the second electrode side, and
the first insulating layer may be provided on a side surface of the first taper section.

With the light emitting device, light generated in the first light emitting layer can be reflected on the side surface of the first taper section toward the second electrode.

In the light emitting device according to the aspect,
the first lens may include:
an emission surface that emits light generated in the first light emitting layer; and
a second taper section, width of which increases from the first transparent layer side toward the emission surface side, and
the reflective member may be in contact with a side surface of the second taper section.

With the light emitting device, the light generated in the first light emitting layer can be reflected on the side surface of the second taper section toward the emission surface side.

In the light emitting device according to the aspect, the emission surface may be a curved surface.

With the light emitting device, for example, the light generated in the first light emitting layer can be collected.

In the light emitting device according to the aspect, the first transparent layer may have insulation.

With the light emitting device, the possibility of the second electrode being etched can be further reduced.

In the light emitting device according to the aspect, the first transparent layer may have electric conductive.

With the light emitting device, an electric current injected into the first light emitting layer can be further increased.

Electronic equipment according to an aspect includes the light emitting device according to the aspect explained above.

What is claimed is:

1. A light emitting device including:
a substrate;
a first stacked body including a first semiconductor layer of a first conductivity type, a second semiconductor layer of a second conductivity type different from the first conductivity type, and a first light emitting layer provided between the first semiconductor layer and the second semiconductor layer;
a first insulating layer provided on a side surface of the first stacked body;
a first metal layer provided on the first insulating layer and located on a side of the first stacked body;
a first electrode provided between the substrate and the first stacked body and electrically coupled to the first semiconductor layer;
a second electrode provided on a side of the first stacked body opposite to the first electrode and electrically coupled to the second semiconductor layer;
a first transparent layer provided on a side of the second electrode opposite to the first stacked body;
a first lens provided on a side of the first transparent layer opposite to the second electrode and overlapping the first light emitting layer in a plan view; and
a reflective member made of metal provided on sides of the first lens and the first transparent layer, wherein
the reflective member is electrically coupled to the second electrode.

2. The light emitting device according to claim 1, further comprising:
a second stacked body including a third semiconductor layer of the first conductivity type, a fourth semiconductor layer of the second conductivity type, and a second light emitting layer provided between the third semiconductor layer and the fourth semiconductor layer;
a second insulating layer provided on a side surface of the second stacked body;
a second metal layer provided on the second insulating layer and located on a side of the second stacked body;
a third electrode provided between the substrate and the second stacked body and electrically coupled to the third semiconductor layer;
a fourth electrode provided on a side of the second stacked body opposite to the third electrode and electrically coupled to the fourth semiconductor layer;
a second transparent layer provided on a side of the fourth electrode opposite to the second stacked body; and
a second lens provided on a side of the second transparent layer opposite to the fourth electrode and overlapping the second light emitting layer in the plan view, wherein
the second electrode and the fourth electrode are continuous.

3. The light emitting device according to claim 2, wherein the first insulating layer and the second insulating layer are continuous.

4. The light emitting device according to claim 1, wherein
the first stacked body includes a first taper section, width of which increases from the first electrode side toward the second electrode side, and
the first insulating layer is provided on a side surface of the first taper section.

5. The light emitting device according to claim 1, wherein
the first lens includes:
an emission surface that emits light generated in the first light emitting layer; and
a second taper section, width of which increases from the first transparent layer side toward the emission surface side, and
the reflective member is in contact with a side surface of the second taper section.

6. The light emitting device according to claim 5, wherein the emission surface is a curved surface.

7. The light emitting device according to claim 1, wherein the first transparent layer has insulation.

8. The light emitting device according to claim 1, wherein the first transparent layer has electric conductivity.

9. An electronic equipment comprising the light emitting device according to claim 1.
